(19) United States
(12) Patent Application Publication
(10) Pub. No.: US 2025/0372445 A1
(43) Pub. Date: Dec. 4, 2025

(54) METHOD OF FABRICATING SEMICONDUCTOR SUBSTRATE

(71) Applicant: Taiwan Semiconductor Manufacturing Company, Ltd., Hsinchu (TW)

(72) Inventors: Chung-Yuan Li, Taichung City (TW); Eugene I-Chun Chen, Taipei City (TW); Kuan Liang Liu, New Taipei City (TW); Chia-Shiung Tsai, Hsin-Chu (TW)

(73) Assignee: Taiwan Semiconductor Manufacturing Company, Ltd., Hsinchu (TW)

(21) Appl. No.: 18/677,746

(22) Filed: May 29, 2024

(51) Int. Cl. H01L 21/762

(52) U.S. Cl. CPC H01L 21/76254

(57) ABSTRACT

A method of fabricating a semiconductor substrate includes the following steps. A first dielectric layer and a second dielectric layer are sequentially formed around an aluminum nitride core substrate. A polysilicon layer is formed on a front-side surface, a backside surface and side surfaces of the second dielectric layer. The polysilicon layer is removed from the front-side surface and the side surfaces, so that the polysilicon layer is retained on the backside surface of the second dielectric layer. A barrier oxide layer is formed around the aluminum nitride core substrate, the first and second dielectric layers, and the polysilicon layer. A wafer structure having a splitting plane is bonded onto the barrier oxide layer. A thermal treatment process is performed to mechanically split the wafer structure along the splitting plane into a first portion and a second portion, wherein the first portion is joined to the barrier oxide layer.

### BACKGROUND

Integrated circuits are typically formed on bulk semiconductor substrates. In recent years, semiconductor-on-insulator (SOI) substrates have emerged as an alternative to bulk semiconductor substrates. Devices formed on SOI substrates exhibit many improved characteristics over their bulk substrate counterparts. For example, SOI substrate enables reduced parasitic capacitance, reduced leakage current, reduced latch up, and improved semiconductor device performance (e.g., reduced power consumption and higher switching speed).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 15 are schematic sectional views of various stages in a method of fabricating a semiconductor substrate according to some exemplary embodiments of the present disclosure.

FIG. 16 is a schematic sectional view illustrating a semiconductor structure including devices formed on a semiconductor substrate.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The manufacture of silicon on aluminum nitride (AlN) raw substrate can be used for gallium nitride (GaN) high voltage applications. In general, silicon (Si) can be manufactured on aluminum nitride substrates using a bond and etch-back SOI (BESOI) approach which involves using a stop layer for total thickness variation (TTV) control during the thinning down process. However, the manufacture of silicon on aluminum nitride substrates using the BESOI is more expensive. In some embodiments of the present disclosure, a more cost benefit method for manufacturing silicon on aluminum substrates will be described.

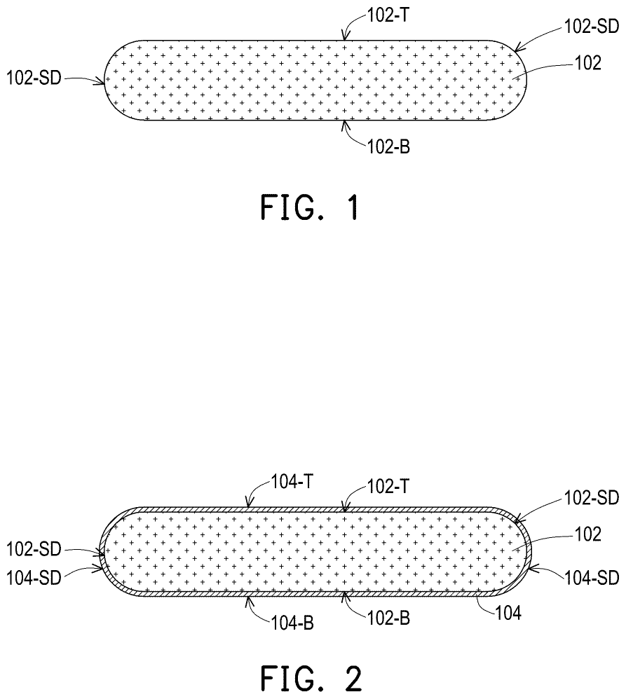

FIG. 1 to FIG. 15 are schematic sectional views of various stages in a method of fabricating a semiconductor substrate according to some exemplary embodiments of the present disclosure. In some embodiments, a first wafer structure WF1 is initially formed by referring to the steps shown in FIG. 1 to FIG. 6. As illustrated in FIG. 1, a core substrate 102 is provided. In some embodiments, the core substrate 102 may be referred to as a carrier substrate or a semiconductor substrate. In some embodiments, the core substrate 102 is an aluminum nitride core substrate, which is a ceramic that is made by compressing aluminum nitride powder, and performing sintering at approximately 2000° C. As illustrated in FIG. 1, the core substrate 102 has a front-side surface 102-T, a backside surface 102-B and side surfaces 102-SD. For example, the front-side surface 102-T and the backside surface 102-B are opposite to one another, while the side surfaces 102-SD are joining the front-side surface 102-T to the backside surface 102-B. In some embodiments, the side surfaces 102-SD are curved side surfaces, but the disclosure is not limited thereto. In other embodiments, the side surfaces 102-SD are planar surfaces.

Referring to FIG. 2, in a subsequent step, a polysilicon layer (not shown) may be formed on the core substrate 102. For example, the polysilicon layer may be formed so that it is wrapping around the core substrate 102, and is covering and contacting the front-side surface 102-T, the backside surface 102-B and the side surfaces 102-SD of the core substrate 102. In some embodiments, the polysilicon layer may be formed by a deposition process such as chemical vapor deposition (CVD), an epitaxial process, or the like. Furthermore, the polysilicon layer may be formed with a thickness in a range of 0.02 μm to 2 μm. In certain embodiments, the polysilicon layer may be formed with a thickness in a range of 0.02 μm to 0.5 μm.

In some embodiments, a thermal oxidation process may be performed on the polysilicon layer, so that the polysilicon layer is reacted to form a first dielectric layer 104 on the core substrate 102. For example, the first dielectric layer 104 is a silicon oxide (SiO₂) layer. After the thermal oxidation process, the first dielectric layer 104 is wrapping around the core substrate 102, and is in physical contact with the front-side surface 102-T, the backside surface 102-B and the side surfaces 102-SD of the core substrate 102. In some embodiments, the first dielectric layer 104 is formed with a thickness in a range of 0.05 μm to 5 μm. In certain embodiments, the first dielectric layer 104 is formed with a thickness in a range of 0.1 μm to 1 μm. As illustrated in FIG. 2, the first dielectric layer 104 has a front-side surface 104-T, a backside surface 142-B and side surfaces 104-SD. For example, the front-side surface 104-T and the backside surface 104-B are opposite to one another, while the side surfaces 104-SD are joining the front-side surface 104-T to the backside surface 104-B.

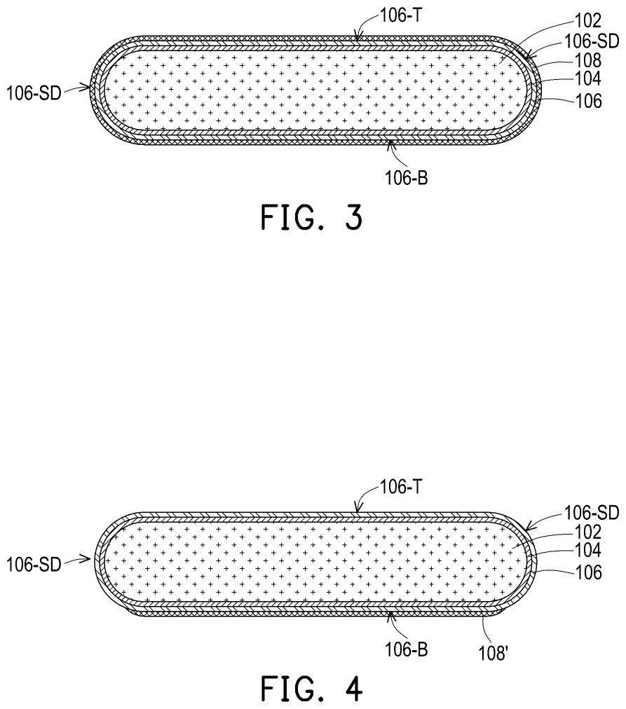

Referring to FIG. 3 in a subsequent step, a second dielectric layer 106 and a polysilicon layer 108 are sequentially formed over the first dielectric layer 104 to surround the core substrate 102. For example, the second dielectric layer 106 is wrapping around the first dielectric layer 104, and is covering and contacting the front-side surface 104-T, the backside surface 104-B and the side surfaces 104-SD of the first dielectric layer 104. Furthermore, the polysilicon layer 108 is wrapping around the second dielectric layer 106, and is covering and contacting a front-side surface 106-T, the backside surface 106-B and side surfaces 106-SD of the second dielectric layer 106. The second dielectric layer 106 is sandwiched between the first dielectric layer 104 and the polysilicon layer 108.

In some embodiments, the second dielectric layer 106 includes a dielectric material such as silicon nitride (SiN), or the like. Furthermore, the second dielectric layer 106 may be formed on the first dielectric layer 104 by a deposition process, such as low-pressure chemical vapor deposition (LPCVD), or the like. In some embodiments, the second dielectric layer 106 may be formed with a thickness in a range of 0.05 μm to 1 μm. In some embodiments, the polysilicon layer 108 includes doped polysilicon, undoped polysilicon, which may be formed by a deposition process such as CVD, an epitaxial process, or the like. In certain embodiments, the polysilicon layer 108 may be formed with a thickness in a range of 0.02 μm to 0.5 μm. As illustrated in FIG. 3, the first dielectric layer 104 is formed in between (or sandwiched in between) the core substrate 102 and the second dielectric layer 106. Furthermore, the second dielectric layer 106 is formed in between (or sandwiched in between) the first dielectric layer 104 and the polysilicon layer 108.

Referring to FIG. 4, after forming the polysilicon layer 108, portions of the polysilicon layer 108 are removed by an etching process, such as by a single wafer wet etch process. As illustrated in FIG. 4, the polysilicon layer 108 located on the front-side surface 106-T and the side surfaces 106-SD of the second dielectric layer 106 are removed by the etching process, while a portion of the polysilicon layer 108 (the etched polysilicon layer 108′) is retained on the backside surface 106-B of the second dielectric layer 106. In other words, the front-side surface 106-T and the side surfaces 106-SD of the second dielectric layer 106 are revealed after the etching process. In some embodiments, the etched polysilicon layer 108′ is located over a backside surface 102-B of the core substrate 102.

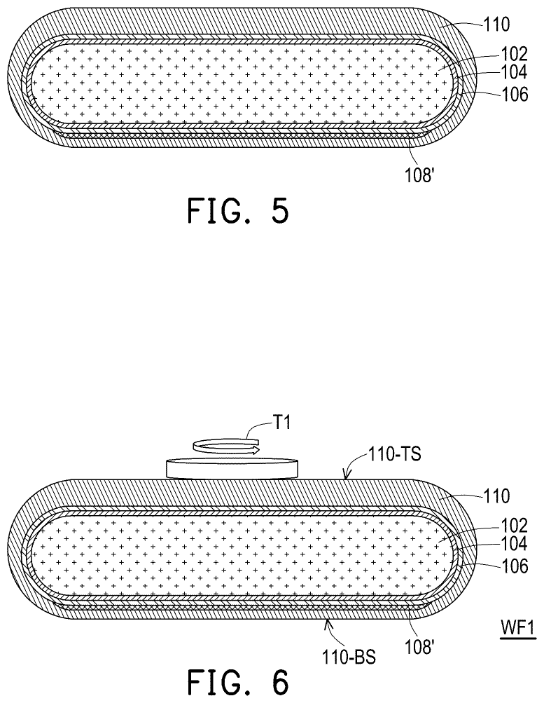

Referring to FIG. 5, in a subsequent step, a barrier oxide layer 110 is formed to surround the etched polysilicon layer 108′, the second dielectric layer 106, the first dielectric layer 104, and the core substrate 102. For example, the barrier oxide layer 110 is wrapping around the etched polysilicon layer 108′, the second dielectric layer 106, the first dielectric layer 104, and the core substrate 102, and is physically contacting the etched polysilicon layer 108′ and the second dielectric layer 106. For example, the barrier oxide layer 110 may be contacting two opposing ends (or terminals) of the etched polysilicon layer 108′, and contacting a backside surface of the etched polysilicon layer 108′. In some embodiments, the etched polysilicon layer 108′ is sandwiched in between the second dielectric layer 106 and the barrier oxide layer 110. In certain embodiments, the barrier oxide layer 110 includes an oxide material, such as silicon oxide (SiO₂), or the like. For example, the silicon oxide (SiO₂) may be formed from tetraethyl orthosilicate (TEOS) by suitable deposition techniques, such as plasma-enhanced chemical vapor deposition (PECVD), or the like. In some embodiments, the barrier oxide layer 110 is formed with a thickness in a range of 1 μm to 5 μm.

Referring to FIG. 6, a thinning process T1, such as a chemical mechanical polishing (CMP) process, is performed on a front-side surface 110-TS and a backside surface 110-BS of the barrier oxide layer 110, to thin-down or to reduce a thickness of the barrier oxide layer 110 from the front-side surface 110-TS and the backside surface 110-BS. For example, a ratio (X1:X2) of an average thickness X1 of the barrier oxide layer 110 before the thinning process T1 and an average thickness X2 of the barrier oxide layer 110 after the thinning process T1 may be in a range of 1:0.2 to 1:0.6. After the thinning process T1, a first wafer structure WF1 according to some embodiments of the present disclosure may be accomplished. In some embodiments, the barrier oxide layer 110 has a greater thickness on the front-side surface 110-TS, while having a relatively smaller thickness on the backside surface 110-BS. In other words, the portion of the barrier oxide layer 110 in contact with the etched polysilicon layer 108′ may be thinner than the remaining portions of the barrier oxide layer 110 that are in contact with the front-side surface 106-T and side surfaces 106-SD of the second dielectric layer 106.

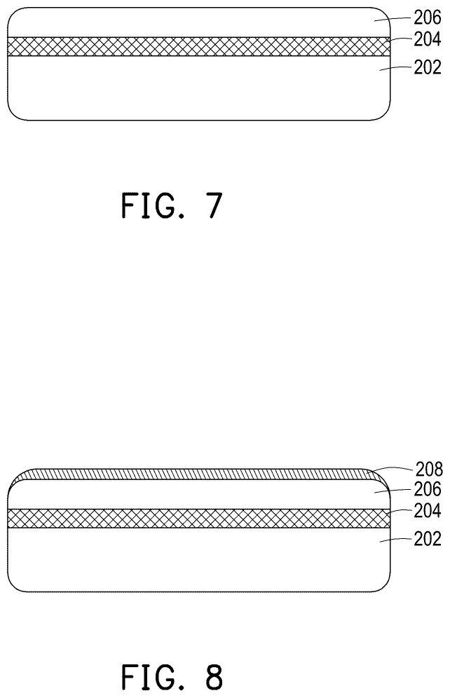

After forming the first wafer structure WF1, the steps illustrated in FIG. 7 to FIG. 11 may then be performed to form a second wafer structure WF2 in accordance with some embodiments of the present disclosure. As illustrated in FIG. 7, a wafer substrate 202 is provided. The wafer substrate 202 is a semiconductor wafer, such as a silicon wafer. The wafer substrate 202 may include monocrystalline silicon having a (111) crystal orientation. In some embodiments, the wafer substrate 202 may be undoped or lightly doped. For example, the wafer substrate 202 and may be a p-type substrate or a n-type substrate. In some embodiments, a buffer layer 204 is formed on a top surface of the wafer substrate 202 to contact the wafer substrate 202. In some embodiments, the buffer layer 204 includes semiconductor materials, and may include elements selected from group IIIA, group IVA. In certain embodiments, the buffer layer 204 includes silicon germanium (SiGe), which may be formed by an epitaxial process. The buffer layer 204 may be doped or undoped. For example, in some embodiments, the buffer layer 204 is a silicon germanium layer doped with boron (SiGe:B). In some embodiments, a thickness of the buffer layer 204 may be in a range of 10 nm to 100 nm. However, the disclosure is not limited thereto, and the thickness of the buffer layer 204 may be adjusted based on the requirements of the implanting process and splitting process performed in subsequent steps.

As further illustrated in FIG. 7, a capping layer 206 is formed over the buffer layer 204, and is directly contacting the buffer layer 204. In some embodiments, the capping layer 206 include monocrystalline silicon having a (111) crystal orientation. In some embodiments, the capping layer 206 is doped or undoped, and is formed on the buffer layer 204 by an epitaxial process. In certain embodiments, a thickness of the capping layer 206 may be in a range from 15 nm to 500 nm, which may be adjusted based on design requirement. In some embodiments, the buffer layer 204 is sandwiched in between the wafer substrate 202 and the capping layer 206.

Referring to FIG. 8, in a subsequent step, a protection layer 208 is formed on the capping layer 206. For example, the protection layer 208 includes an oxide material, such as silicon oxide (SiO₂), or the like. In some embodiments, the protection layer 208 is formed by a suitable deposition process, such as high density plasma CVD (HDP-CVD), or the like. In some embodiments, a thickness of the protection layer 208 is in a range of 10 nm to 200 nm, but the disclosure is not limited thereto. In certain embodiments, the thickness of the protection layer 208 may be adjusted based on the desired implantation depth of the subsequent implantation process.

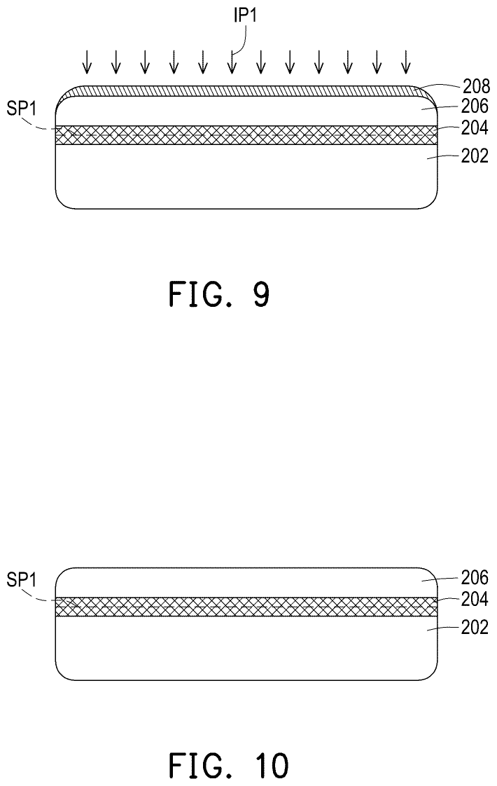

Referring to FIG. 9, after forming the protection layer 208, an implantation process IP1 is performed to the buffer layer 204 to generate a splitting plane SP1 in the buffer layer 204. In, some embodiments, the implantation process IP1 includes performing a hydrogen implanting process to implant hydrogen ions (H⁺) through the protection layer 208 and the capping layer 206, and into the buffer layer 204 to generate the splitting plane SP1. In some embodiments, the capping layer 206 is protected by the protection layer 208 from being damaged by the ion bombardment during the implantation process.

In some embodiments, the implantation process IP1 may be performed at an energy of 5-100 KeV using a dosage (e.g., hydrogen dosage) of 1×10¹⁶ ions/cm² to 1×10¹⁸ ions/cm². In some embodiments, all or most of the hydrogen ions are implanted into the buffer layer 204, while minor or almost none of the hydrogen ions are implanted into the capping layer 206 and/or the wafer substrate 202. In other words, the buffer layer 204 has the highest concentration of the implanted ions, while the other layers has minimal concentration of the implanted ions. In some embodiments, the implantation process IP1 of implanting the hydrogen ions generates a gradient layer of hydrogen ions in the buffer layer 204. In other words, the hydrogen ions may be distributed throughout the depth/thickness of the buffer layer 204 with gradient concentration of the hydrogen ions.

In the exemplary embodiment, a region in the gradient layer within the buffer layer 204 having a highest hydrogen ion (H⁺) concentration corresponds to the splitting plane SP1. For example, in one embodiment, if the hydrogen ion concentration in the buffer layer 204 is highest in a region that is closer to the capping layer 206, then the splitting plane SP1 will also be closer to the capping layer 206. On the other hand, if the hydrogen ion concentration in the buffer layer 204 is highest in a region that is closer to wafer substrate 202, then the splitting plane SP1 will also be closer to the wafer substrate 202. In some embodiments, if the hydrogen ion concentration in the buffer layer 204 is highest in a middle region of the buffer layer 204, then the splitting plane SP1 will also be located in the middle region of the buffer layer 204. In some embodiments, the implantation process IP1 is controlled so that the splitting plane SP1 is generated within the buffer layer 204. Furthermore, although the splitting plane SP1 is illustrated as a dotted line, it should be understood that the splitting plane SP1 may have a certain thickness that correspond to a region in the buffer layer 204 having high concentration of the implanted species.

Referring to FIG. 10, in a subsequent step, after performing the implantation process IP1, the protection layer 208 may be removed. For example, the protection layer 208 is removed to reveal a top surface of the capping layer 206 located underneath. In some embodiments, the removal of the protection layer 208 is performed by an etching process, such as a wet etching process, a dry etching process, or a combination thereof. In certain embodiments, the protection layer 208 is removed by a wet etching process using diluted HF/nitric acid/acetic acid (dHNA).

Thereafter, referring to FIG. 11, a bonding layer 210 is formed on the capping layer 206, and physically contacting a top surface of the capping layer 206. In some embodiments, a material of the bonding layer 210 may be the same as a material of the barrier oxide layer 110, whereby the bonding layer 210 is intended for bonding to the barrier oxide layer 110 in subsequent steps. However, the disclosure is not limited thereto, and other materials may be used as the bonding layer 210 as long as the bonding layer 210 can be chemically bonded to the barrier oxide layer 110 in the subsequent steps. In the exemplary embodiment, the bonding layer 210 may be an oxide material, such as silicon oxide (SiO₂), or the like, and may formed by a suitable deposition process, such as HDP-CVD, or the like. In some embodiments, the bonding layer 210 and the protection layer 208 may be formed of the same material, or may be formed of different materials. In some embodiments, a thickness of the bonding layer 210 is in a range of 10 nm to 500 nm. After forming the bonding layer 210, a second wafer structure WF2 in accordance with some embodiments of the present disclosure may be accomplished.

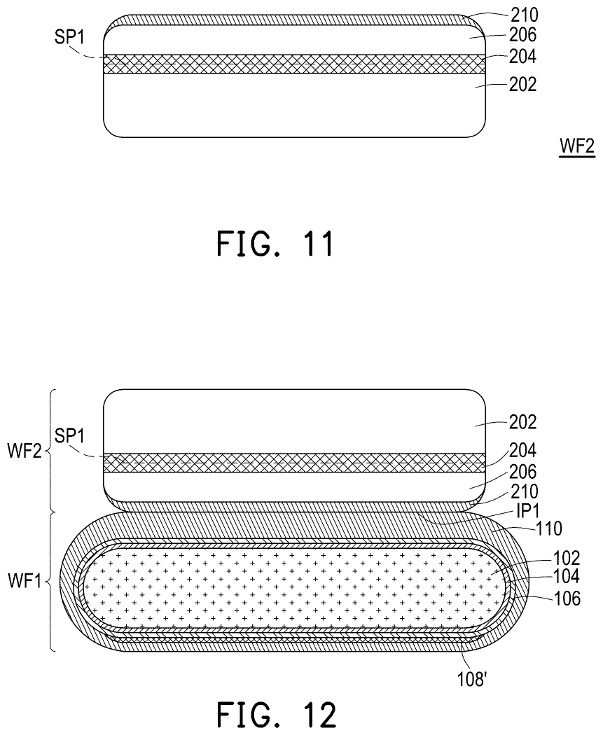

Referring to FIG. 12, after forming the first wafer structure WF1 illustrated in FIG. 6 and forming the second wafer structure WF2 illustrated in FIG. 11, a wafer bonding process is performed by bonding the second wafer structure WF2 to the first wafer structure WF1. In some embodiments, a size (e.g., width, area) of the second wafer structure WF2 is smaller than a size (e.g., width, area) of the first wafer structure WF1. For example, sidewalls of the first wafer structure WF1 may be protruding out over sidewalls of the second wafer structure WF2 after the wafer bonding process. However, the disclosure is not limited thereto, and the wafer bonding process described herein may be applied to wafers having the same size or different sizes, which may be adjusted based on actual requirement.

In some embodiments, during the wafer bonding process, the second wafer structure WF2 is flipped upside down so that the bonding layer 210 is facing the barrier oxide layer 110 of the first wafer structure WF1. Thereafter, in some embodiments, the wafer bonding process is conducted by performing a bond annealing process to join the bonding layer 210 of the second wafer structure WF2 to the barrier oxide layer 110 of the first wafer structure WF1. In some embodiments, the bond annealing process is performed at a temperature of 300° C. to 1000° C. By heating the bonding surfaces at such elevated temperature, the bonding between the bonding layer 210 and the barrier oxide layer 110 may be ensured. For example, in some embodiments, the bonding between the bonding layer 210 and the barrier oxide layer 110 may include covalent bonds. In some other embodiments, an interface IP1 can be observed between the bonding layer 210 and the barrier oxide layer 110 after bonding.

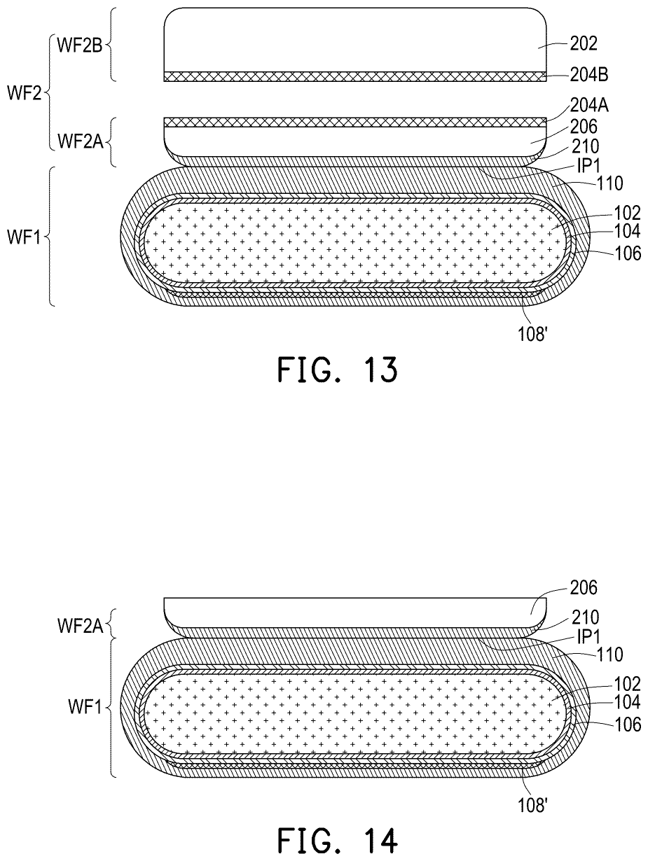

Referring to FIG. 13, after bonding the second wafer structure WF2 to the first wafer structure WF1, a splitting process is performed to split the second wafer structure WF2 from the first wafer structure WF1 by inducing splitting at the splitting plane SP1. In some embodiments, the splitting at the splitting plane SP1 is induced by performing a thermal treatment process to the buffer layer 204 of the second wafer structure WF2. For example, the thermal treatment process is performed at a temperature that is lower than a temperature of the bond anneal process during wafer bonding. In some embodiments, the thermal treatment process for inducing splitting is performed at a temperature of less than 400° C. In certain embodiments, the thermal treatment process for inducing splitting is performed at a temperature range of 200° C. to 600° C. In some other embodiments, the thermal treatment process for inducing splitting is performed at a temperature of 400° C. or less, and performed at a temperature range of 200° C. to 400° C. In the exemplary embodiment, due to the thermal treatment process, hydrogen ions will generate gaseous bubbles at the splitting plane SP1 of the buffer layer 204. As such, the splitting process may be performed by mechanically splitting the second wafer structure WF2 from the first wafer structure WF1 at the splitting plane SP1 due to the presence of bubbles.

As a result, the splitting process will split the second wafer structure WF2 along the splitting plane SP1 into a first portion WF2A and a second portion WF2B. For example, the first portion WF2A is retained on the first wafer structure WF1, while the second portion WF2B is split or removed from the first wafer structure WF1. In the exemplary embodiment, the first portion WF2A of the second wafer structure WF2 is directly joined with/disposed on the barrier oxide layer 110 of the first wafer structure WF1, and includes the bonding layer 210, the capping layer 206 and a first buffer portion 204A of the buffer layer 204. Furthermore, the second portion WF2B of the second wafer structure WF2 removed from the first wafer structure WF1 includes the wafer substrate 202 and a second buffer portion 204B of the buffer layer 204. In other words, the splitting process also includes splitting the buffer layer 204 at the splitting plane SP1 into the first buffer portion 204A and the second buffer portion 204, whereby the first buffer portion 204A is retained on the first wafer structure WF1, and the second buffer portion 204B is removed along with the second portion WF2B of the second wafer structure WF2.

Referring to FIG. 14, after performing the splitting process an acid etching process is performed to remove the first buffer portion 204A of the buffer layer 204 to reveal the capping layer 206. For example, the first buffer portion 204A of the buffer layer 204 may be removed by an etching process, such as a dry etching process, a wet etching process, or a combination thereof. In certain embodiments, the first buffer portion 204A is removed by a wet etching process using diluted HF/nitric acid/acetic acid (dHNA). In some embodiments, the capping layer 206 may also be partly etched or partially removed by the etching process.

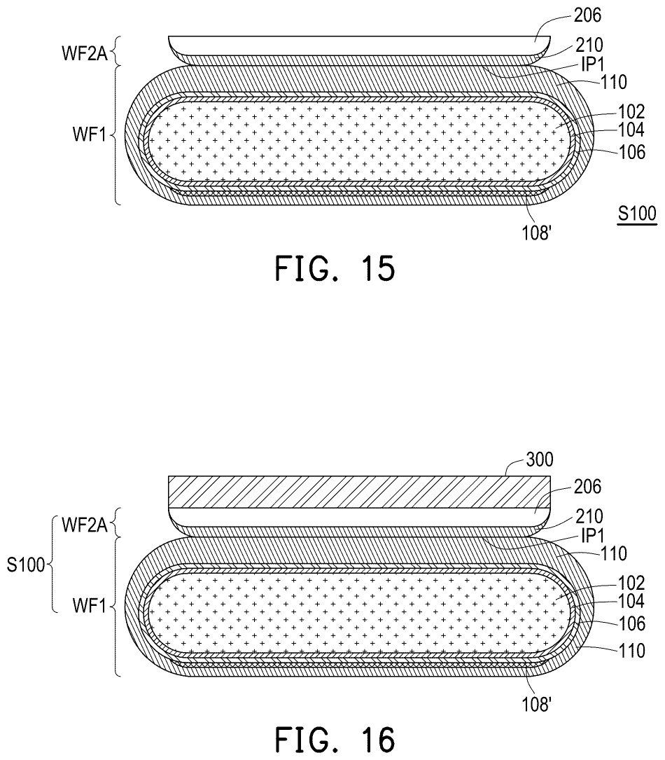

Thereafter, referring to FIG. 15, a thinning step, such as a chemical mechanical polishing (CMP) process, may be performed on the capping layer 206 so that the capping layer has a substantially planar top surface. Thereafter, an annealing process, or a post annealing process may be performed to remove defects included (if any) in the capping layer 206. For example, the post annealing process may be performed in a temperature range of from 1000° C. to 1200° C. so that implant induced defects (defects caused by the formation of bubbles) in the capping layer 206 are healed. Up to here, a semiconductor substrate S100 in accordance with some embodiments of the present disclosure may be accomplished.

In the exemplary embodiment, the semiconductor substrate S100 may also be referred to as a semiconductor-on-insulator (SOI) substrate. For example, the semiconductor substrate S100 includes the first wafer structure WF1 and the first portion WF2A of the second wafer structure WF2 located thereon. The first wafer structure WF1 includes the core substrate 102, the first dielectric layer 104, the second dielectric layer 106, the etched polysilicon layer 108′ and the barrier oxide layer 100. The first portion WF2A of the second wafer structure WF2 includes a capping layer 206 and a bonding layer 210.

As illustrated in the semiconductor substrate S100 of FIG. 15, the core substrate 102 is surrounded by the first dielectric layer 104, the second dielectric layer 106 and the barrier oxide layer 110, whereby the etched polysilicon layer 108′ is located on backside surfaces of the core substrate 102, and sandwiched in between the second dielectric layer 106 and the barrier oxide layer 110. For example, the first dielectric layer 104 is entirely wrapping around the core substrate 102, the second dielectric layer 106 is entirely wrapping around the first dielectric layer 104 and the core substrate 102, while the barrier oxide layer 110 is wrapping around all of the first dielectric layer 104, the second dielectric layer 106 and the etched polysilicon layer 108′. Furthermore, the bonding layer 210 is physically attached to a top surface of the barrier oxide layer 110, while the capping layer 206 is disposed on the bonding layer 210, and is physically separated by the barrier oxide layer 110 by the bonding layer 210. The semiconductor substrate S100 (or SOI substrate) may be used as the raw substrate for various applications. For example, the semiconductor substrate S100 is used as a raw substrate for gallium nitride (GaN) high voltage applications. In some embodiments, the surface of the semiconductor substrate S100 is monocrystalline (e.g. the capping layer 206), so that a III-nitride (e.g., GaN, AlN, AlGaN, InGaN) or any other suitable crystalline material, such as III-V, II-VI, tertiary, or quaternary semiconductor materials, may be epitaxially grown from the surface of the semiconductor substrate S100 based on product requirement.

FIG. 16 is a schematic sectional view illustrating a semiconductor structure including devices formed on a semiconductor substrate. As illustrated in FIG. 16, in some embodiments, a device layer 300 may be formed on the capping layer 206 of the semiconductor substrate S100 for various application. For example, the device layer 300 may include active components, passive components, or a combination thereof. In some other embodiments, the device layer 300 include integrated circuits devices. The device layer 300 includes, for example, transistors, capacitors, resistors, diodes, photodiodes, fuse devices, or other similar devices. In an embodiment, the device layer 300 includes a gate structure, source and drain regions, and isolation structures such as shallow trench isolation (STI) structures (not shown). In the device layer 300, various N-type metal-oxide semiconductor (NMOS) and/or P-type metal-oxide semiconductor (PMOS) devices, such as transistors or memories and the like, may be formed and interconnected to perform one or more functions

In the above-mentioned embodiments, the semiconductor substrate is formed by forming a first wafer structure, whereby the first wafer structure comprises an aluminum nitride core substrate and a barrier oxide layer wrapping around the aluminum nitride core substrate. A second wafer structure having a buffer layer and a bonding layer is bonded to the first wafer structure, whereby the buffer layer is implanted to generate a splitting plane in the buffer layer. As such, a thermal treatment process may be performed on the buffer layer, to induce a splitting process at the splitting plane of the buffer layer. Therefore, the manufacture of silicon on aluminum nitride (AlN) raw substrate can be efficiently achieved by low-temperature layer transfer, which is a more cost benefit method.

In accordance with some embodiments of the present disclosure, a method of fabricating a semiconductor substrate is described. The method includes the follow steps. Forming a first wafer structure by: forming a first dielectric layer surrounding a core substrate; forming a second dielectric layer on the first dielectric layer and surrounding the first dielectric layer; and forming a barrier oxide layer surrounding the first dielectric layer, the second dielectric layer and the core substrate. Forming a second wafer structure, by: forming a buffer layer over a wafer substrate; sequentially forming a capping layer and a protection layer on the buffer layer; performing a hydrogen implanting process to implant hydrogen ions into the buffer layer to generate a splitting plane in the buffer layer; and removing the protection layer to reveal the capping layer. Bonding the second wafer structure to the first wafer structure by performing a bond annealing process to join the capping layer to the barrier oxide layer. Performing a thermal treatment process to the buffer layer of the second wafer structure. Performing a splitting process to split the second wafer structure from the first wafer structure by inducing splitting at the splitting plane.

In accordance with some other embodiments of the present disclosure, a method of fabricating a semiconductor substrate includes the following steps. A first dielectric layer and a second dielectric layer are sequentially formed to wrap around an aluminum nitride core substrate. A polysilicon layer is formed on a front-side surface, a backside surface and side surfaces of the second dielectric layer. The polysilicon layer is removed from the front-side surface and the side surfaces of the second dielectric layer, so that the polysilicon layer is retained on the backside surface of the second dielectric layer. A barrier oxide layer is formed to wrap around the aluminum nitride core substrate, the first dielectric layer, the second dielectric layer and the polysilicon layer. A wafer structure is bonded onto the barrier oxide layer, wherein the wafer structure comprises a splitting plane. A thermal treatment process is performed to mechanically split the wafer structure along the splitting plane into a first portion and a second portion, wherein the first portion is joined to the barrier oxide layer, and the second portion is separated from the first portion and removed from being on the barrier oxide layer.

In accordance with yet another embodiment of the present disclosure, a method of fabricating a semiconductor substrate includes the following steps. A first wafer structure having an aluminum nitride core substrate and a barrier oxide layer wrapping around the aluminum nitride core substrate is formed. A second wafer structure having a buffer layer and a bonding layer is formed. An implantation process is performed on the buffer layer to generate a splitting plane in the buffer layer. A bond annealing steps is performed at a temperature of 300° C. to 1000° C. to bond the bonding layer of the second wafer structure to the barrier oxide layer of the first wafer structure. A thermal treatment process is performed at a temperature lower than the bond annealing step, and a splitting process is performed to split the buffer layer at the splitting plane.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor substrate, comprising:
forming a first wafer structure, comprising:
forming a first dielectric layer surrounding a core substrate;
forming a second dielectric layer on the first dielectric layer and surrounding the first dielectric layer; and
forming a barrier oxide layer surrounding the first dielectric layer, the second dielectric layer and the core substrate;
forming a second wafer structure, comprising:
forming a buffer layer over a wafer substrate;
sequentially forming a capping layer and a protection layer on the buffer layer;
performing a hydrogen implanting process to implant hydrogen ions into the buffer layer to generate a splitting plane in the buffer layer; and
removing the protection layer to reveal the capping layer;
bonding the second wafer structure to the first wafer structure by performing a bond annealing process to join the capping layer to the barrier oxide layer;
performing a thermal treatment process to the buffer layer of the second wafer structure; and
performing a splitting process to split the second wafer structure from the first wafer structure by inducing splitting at the splitting plane.

2. The method according to claim 1, wherein the thermal treatment process generates bubbles at the splitting plane of the buffer layer, and the splitting process includes mechanically splitting the second wafer structure from the first wafer structure at the splitting plane.

3. The method according to claim 1, wherein the thermal treatment process is performed at a temperature that is lower than a temperature of the bond anneal process.

4. The method according to claim 1, further comprising forming a polysilicon layer in between the second dielectric layer and the barrier oxide layer.

5. The method according to claim 1, wherein forming the second wafer structure further comprises:
after removing the protection layer to reveal the capping layer, forming a bonding layer on the capping layer, and
wherein bonding the second wafer structure to the first wafer structure includes physically joining the bonding layer to the barrier oxide layer by the bond annealing process.

6. The method according to claim 1, wherein the splitting process includes splitting the buffer layer at the splitting plane into a first buffer portion and a second buffer portion, wherein after the splitting process, the first buffer portion is retained on the first wafer structure, and the second buffer portion is removed along with the second wafer structure.

7. The method according to claim 6, further comprising performing an acid etching process to remove the first buffer portion to reveal the capping layer.

8. A method of fabricating a semiconductor substrate, comprising:
sequentially forming a first dielectric layer and a second dielectric layer wrapping around an aluminum nitride core substrate;
forming a polysilicon layer on a front-side surface, a backside surface and side surfaces of the second dielectric layer;
removing the polysilicon layer from the front-side surface and the side surfaces of the second dielectric layer, so that the polysilicon layer is retained on the backside surface of the second dielectric layer;
forming a barrier oxide layer wrapping around the aluminum nitride core substrate, the first dielectric layer, the second dielectric layer and the polysilicon layer;
bonding a wafer structure onto the barrier oxide layer, wherein the wafer structure comprises a splitting plane; and
performing a thermal treatment process to mechanically split the wafer structure along the splitting plane into a first portion and a second portion, wherein the first portion is joined to the barrier oxide layer, and the second portion is separated from the first portion and removed from being on the barrier oxide layer.

9. The method according to claim 8, wherein the first dielectric layer is silicon oxide, the second dielectric layer is silicon nitride and the barrier oxide layer is silicon oxide.

10. The method according to claim 8, wherein the wafer structure comprising the splitting plane is formed by implanting hydrogen ions into a buffer layer of the wafer structure, and wherein implanting the hydrogen ions generates a gradient layer of hydrogen ions in the buffer layer, and a region in the gradient layer having a highest hydrogen ion concentration corresponds to the splitting plane.

11. The method according to claim 10, wherein the buffer layer comprises silicon germanium.

12. The method according to claim 10, wherein the first portion of the wafer structure comprises a bonding layer that is bonded to the barrier oxide layer, a capping layer disposed on the bonding layer and a first buffer portion of the buffer layer.

13. The method according to claim 8, wherein bonding the wafer structure onto the barrier oxide layer comprises performing a bond annealing process at a temperature of 300° C. to 1000° C.

14. The method according to claim 8, wherein the thermal treatment process is performed at a temperature of less than 400° C.

15. A method of fabricating a semiconductor substrate, comprising:
forming a first wafer structure having an aluminum nitride core substrate and a barrier oxide layer wrapping around the aluminum nitride core substrate;
forming a second wafer structure having a buffer layer and a bonding layer;
performing an implantation process on the buffer layer to generate a splitting plane in the buffer layer;
performing a bond annealing step at a temperature of 300° C. to 1000° C. to bond the bonding layer of the second wafer structure to the barrier oxide layer of the first wafer structure; and
performing a thermal treatment process at a temperature lower than the bond annealing step, and performing a splitting process to split the buffer layer at the splitting plane.

16. The method according to claim 15, wherein forming the first wafer structure further comprises:
forming a silicon oxide layer wrapping around the aluminum nitride core substrate;
forming a silicon nitride layer wrapping around the silicon oxide layer;
forming a polysilicon layer on the silicon nitride layer over a backside of the aluminum nitride core substrate; and
forming the barrier oxide layer wrapping around the polysilicon layer, the silicon nitride layer, the silicon oxide layer and the aluminum nitride core substrate, wherein the barrier oxide layer is in physical contact with the polysilicon layer and the silicon nitride layer.

17. The method according to claim 15, wherein forming the second wafer structure comprise:
forming the buffer layer on a wafer substrate;
forming a capping layer and a protection layer on the buffer layer;
performing the implantation process to generate the splitting plane in the buffer layer;
removing the protection layer to reveal the capping layer; and
forming the bonding layer on the capping layer.

18. The method according to claim 17, wherein after the splitting process, the bonding layer, the capping layer and a portion of the buffer layer is retained on the first wafer structure.

19. The method according to claim 18, further comprises performing an etching process to remove the portion of the buffer layer to reveal the capping layer, and performing a thinning step on the capping layer.

20. The method according to claim 15, wherein the thermal treatment process is performed at the temperature of 400° C. or less.
